(19) United States
(12) Patent Application Publication
(10) Pub. No.: US 2008/0283938 A1
(43) Pub. Date: Nov. 20, 2008

(54) Semiconductor device and method for manufacturing the same

(75) Inventor: Mun Sub Hwang, Yuseong-gu (KR)

Correspondence Address: FINNEGAN, HENDERSON, FARABOW, GARRETT & DUNNER;LLP, 901 NEW YORK AVENUE, NW, WASHINGTON, DC, 20001-4413, US

(73) Assignee: DONGBU HITEK CO., LTD.

(21) Appl. No.: 12/153,338

(22) Filed: May 16, 2008

(30) Foreign Application Priority Data
May 17, 2007 (KR) 10-2007-0047984

(51) Int. Cl. H01L 29/00; H01L 21/8236

(52) U.S. Cl. 257/408; 438/278; 257/E29.001; 257/E21.631

(57) ABSTRACT

Provided are a semiconductor device and a method for manufacturing the same. The semiconductor device may include a substrate having a plurality of isolation areas formed therein, the isolation areas defining an active region, a gate electrode formed on the active region, spacers formed on sides of the gate electrode, a source region formed in the substrate at a side of the spacer formed at a first side of the gate electrode, a drain region formed in the substrate at a side of the spacer formed on a second side of the gate electrode, and lightly doped drain regions formed in the substrate below the spacer.

### RELATED APPLICATIONS

The present application claims the benefit of priority under 35 U.S.C. § 119 to Korean Patent Application No. 10-2007-0047984, filed on May 17, 2007, the entire contents of which are incorporated herein by reference.

### BACKGROUND

Due to the high integration of semiconductor devices, the size of the semiconductor devices becomes so small that achieving desired performance of the semiconductor devices becomes very difficult. For example, as the size of gate/source/drain electrodes of a metal oxide silicon (MOS) transistor becomes smaller, the length of channels also becomes smaller. As a result, the reduced channel length causes a short channel effect (SCE) and a reverse short channel effect (RSCE). Accordingly, it becomes very difficult to control the threshold voltage of the transistor.

Also, since a driving voltage is relatively high despite the dimensional reduction of a high-integrated semiconductor device, electrons injected from a source are severely accelerated in a potential gradient state of a drain to make the drain vulnerable to hot carrier generation. To overcome such a problem, a lightly doped drain (LDD) structure has been proposed to improve the vulnerability of the semiconductor devices.

In a transistor having the LDD structure, a lightly doped (n−) LDD region is formed between a channel and a drain/source to buffer a drain-gate voltage in the vicinity of a drain junction. Hence, the lightly doped LDD region interrupts abrupt potential variation so as to suppress hot carrier generation.

One way to form the LDD structure is to use a spacer on both sidewalls of a gate electrode as a mask.

FIG. 1 is a cross-sectional view illustrating a conventional semiconductor device having an LDD structure.

Referring to FIG. 1, a substrate 10 includes device isolation areas 11, which define an active region. A gate electrode 13, which comprises polysilicon, is formed on substrate 10 in the active region. A gate dielectric layer 12 is formed in the active region between gate electrode 13 and substrate 10.

Ions are implanted into portions of the active region at sides of gate electrode 13 to form LDD regions 14, and sidewalls 18 of SiO₂ are formed on both sides of gate electrode 13.

Spacers 15 of SiN are formed on both sides of sidewalls 18. Sidewalls 18 can buffer stress between spacers 15 and gate electrode 13 and can improve adhesiveness between spacers 15 and gate electrode 13.

A source region 16 and a drain region 17 are respectively formed in portions of the active region at both sides of spacer 15.

Since sidewalls 18 should be formed before the formation of spacer 15, complicated processes, such as deposition, etching, and cleaning processes, need be performed, which can immensely increase the manufacturing time and costs.

Also, since the deposition process for forming spacer 15 is performed at a high temperature for a long time, the distribution of ions implanted into LDD regions 14 will change, which degrades the properties of the semiconductor device.

That is, LDD regions 14 are formed by implanting ions, such as B and BF. However, a heat-treating process for forming spacer 15 promotes the diffusion of the ions toward the edge of a channel region.

Thus, LDD regions 14 diffuse into portions of the semiconductor substrate below edges of gate electrode 13. As a result, in the case where overlap regions A of LDD regions 14 and gate electrode 13 are formed, gate-drain overlap capacitance and RC delay are increased, which may reduce the electric properties of the semiconductor device. For example, operating speed of the semiconductor device may be lowered.

### SUMMARY

In an embodiment consistent with the present invention, a semiconductor device includes a substrate having a plurality of isolation areas formed therein, the isolation areas defining an active region, a gate electrode formed on the active region, spacers formed on sides of the gate electrode, a source region formed in the substrate at a side of the spacer formed at a first side of the gate electrode, a drain region formed in the substrate at a side of the spacer formed on a second side of the gate electrode, and lightly doped drain regions formed in the substrate below the spacer.

In another embodiment consistent with the present invention, a method for manufacturing a semiconductor device includes forming a first oxide layer on a substrate having device isolation areas formed therein, etching a portion of the first oxide layer to expose a portion of the substrate, forming a second oxide layer on the exposed portion of the substrate, the second oxide layer having a thickness less than that of the first oxide layer, embedding a polysilicon layer in the etched portion of the first oxide layer, forming spacers on sides of the polysilicon layer by etching the first oxide layer except for portions of the first oxide layer in contact with side surfaces of the polysilicon layer, and forming lightly doped drain regions in the substrate between the device isolation areas and the spacers.

### BRIEF DESCRIPTION OF THE DRAWINGS

FIG. 1 is a cross-sectional view illustrating a conventional semiconductor device having a lightly doped drain (LDD) structure.

FIGS. 2-8 are cross-sectional views illustrating a method for manufacturing a semiconductor device consistent with embodiments of the present invention.

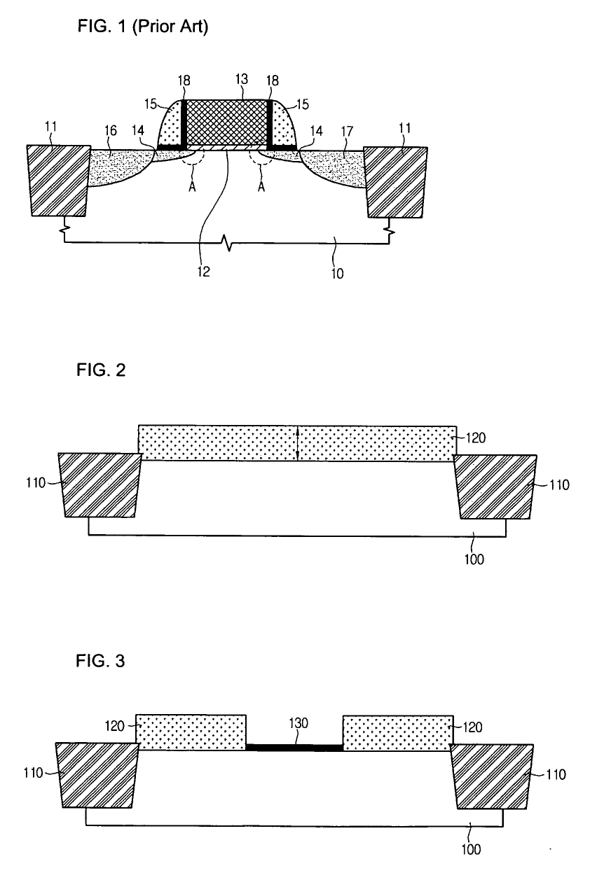

### DETAILED DESCRIPTION

Reference will now be made in detail to embodiments consistent with the present disclosure, examples of which are illustrated in the accompanying drawings.

FIGS. 2-8 are cross-sectional views illustrating a method for manufacturing a semiconductor device according to embodiments consistent with the present invention.

Referring to FIG. 2, device isolation areas 110 are formed to electrically insulate active regions of a semiconductor substrate 100, so as to define an active region. In one embodiment, semiconductor substrate 100 may be a single crystal silicon substrate.

Device isolation areas 110 may be formed in a field region of semiconductor substrate 100 as a dielectric layer, such as an oxide layer, using an isolation process, for example, a shallow trench isolation (STI) process or a local oxidation of silicon (LOCOS) process.

Although not shown, an ion implantation process for adjusting a threshold voltage (V_{T}), an ion implantation process for preventing punch through, an ion implantation process for forming a channel stopper, and an ion implantation process for forming a well may be additionally performed after device isolation areas 110 are formed in semiconductor substrate 100.

Referring again to FIG. 2, a first oxide layer 120 is formed by growing a gate oxide material on the active region of semiconductor substrate 100.

In one embodiment, first oxide layer 120 may have a thickness of about 1,800 Å to about 2,100 Å and may be formed to have a spacer-shape in a subsequent process.

For example, first oxide layer 120 may be formed using a wet oxidation method with a hydrogen gas (H₂) of about 7.5 L/min and an oxygen gas (O₂) of about 9 L/min. If first oxide layer 120 has a thickness of about 1,800 Å, first oxide layer 120 may be formed by performing an oxidation process for approximately 10 hours at a temperature of about 750° C. or for approximately 30 minutes at a temperature of about 1,000° C.

If first oxide layer 120 has a thickness of about 2,100 Å, first oxide layer 120 may be formed by performing an oxidation process for approximately 40 minutes at a temperature of about 1,000° C.

Referring to FIG. 3, a second oxide layer 130 is formed on semiconductor substrate 100.

To form second oxide layer 130 on semiconductor substrate, an etch mask (not shown), such as a photoresist pattern, may be formed on first oxide layer 120 through a photolithography process. In one embodiment, the etch mask may expose a portion of first oxide layer 120 between device isolation areas 110, which corresponds to the location of a gate electrode to be formed in a subsequent process.

After the etch mask is formed on first oxide layer 120, the exposed portion of first oxide layer 120 is removed by performing a dry etching process, so as to expose a portion of semiconductor substrate 100. Then, the photoresist pattern and the etch mask are removed.

Second oxide layer 130 may be formed by growing oxide on the exposed portion of semiconductor substrate 100, as illustrated in FIG. 3.

Second oxide layer 130 may have a thickness less than that of first oxide layer 120 and may function as a gate dielectric layer.

Because semiconductor substrate 100 and first oxide layer 120 have different growth rates or oxidation rates, second oxide layer 130 may be formed on semiconductor substrate 100 as illustrated in FIG. 3.

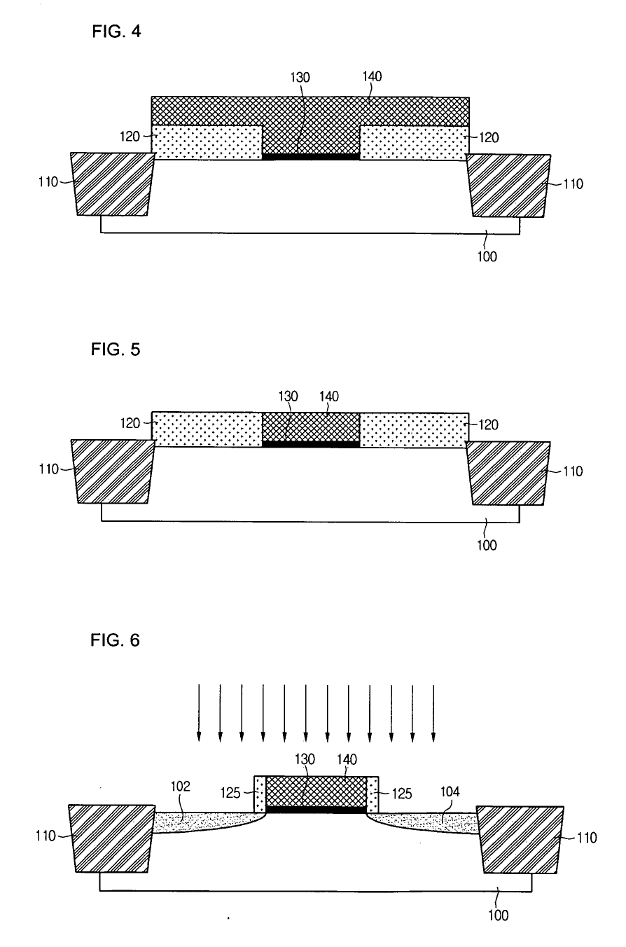

Referring to FIG. 4, a polysilicon layer 140 is formed on first oxide layer 120 and second oxide layer 130. Referring to FIG. 5, polysilicon layer 140 is planarized to expose a surface of first oxide layer 120.

Thus, polysilicon layer 140 is embedded in an etched region of first oxide layer 120, as illustrated in FIG. 5.

Embedded polysilicon layer 140 may function as a gate electrode. Further, a doping process may be performed using ion implantation for heavily-doped impurities. Hereinafter, embedded polysilicon layer 140 is referred to as gate electrode 140.

In one embodiment, the planarization of polysilicon layer 140 may be performed using a grinding process, such as a chemical mechanical polishing (CMP) process. Further, the thickness of gate electrode 140 may be determined according to the thickness of first oxide layer 120 or according to the grinding process of polysilicon layer 140.

Referring to FIG. 6, LDD regions 102 and 104 are formed in semiconductor substrate 100.

After gate electrode 140 is formed, an etch mask (not shown), such as a photoresist pattern, may be formed covering gate electrode 140 and a portion of first oxide layer 120 using a photolithography process.

Then, a portion of first oxide layer 120 not covered by the etch mask is etched or removed. Accordingly, portions of first oxide layer 120 in contact with both sides of gate electrode 140 are not removed.

Thus, the portions of first oxide layer 120 not removed forms a spacer 125, as illustrated in FIG. 6.

In one embodiment, spacer 125 may have a rectangular shape with angled corners. Unlike in the related art, spacer 125 does not require a high-heat treating process.

Impurities, e.g., BF₂ ions for forming LDD regions 102 and 104 in the active region of semiconductor substrate 100 may be implanted in semiconductor substrate 100 using gate electrode 140 as a mask. In one embodiment, an energy of the implantation may be from about 5 KeV to about 50 KeV and a dosage of the implantation may be from about 1×10¹⁴ ions/cm² to about 5×10¹⁵ ions/cm². To form N-type LDD regions, impurities, e.g., arsenic (As) ions may be implanted into the active region with an energy ranging from about 10 KeV to about 70 KeV and a dosage ranging from about 1×10¹⁴ ions/cm² to about 5×10¹⁵ ions/cm².

As shown in FIG. 6, LDD regions 102 and 104 are formed in semiconductor substrate 100 at both sides of gate electrode 140. Further, LDD regions 102 and 104 are formed on semiconductor substrate 100 from device isolation area 110 to somewhere below spacer 125.

Thus, diffusion of LDD regions 102 and 104 toward gate electrode 140 due to a lengthy high-heat treating process may be prevented, and a parasitic capacitance of the semiconductor device may be reduced to improve the electrical properties of the semiconductor device.

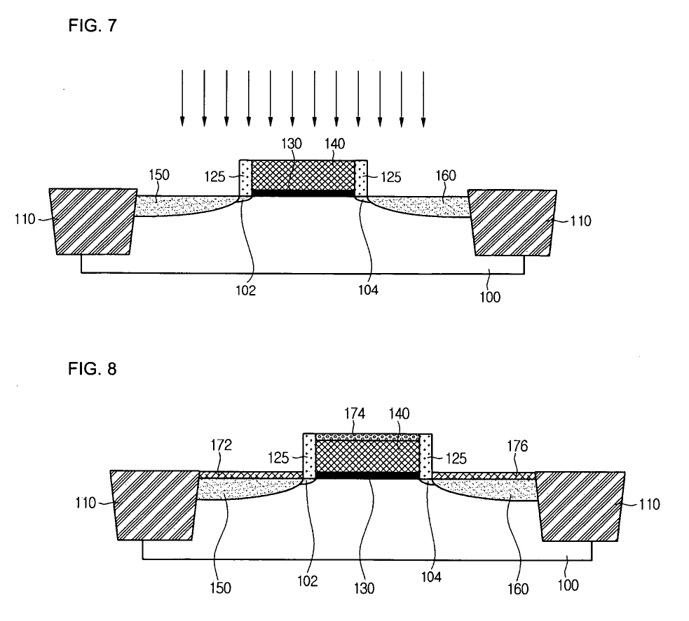

Referring to FIG. 7, a source region 150 and a drain region 160 are formed in semiconductor substrate 100.

P-type impurities, e.g., boron (B) ions for forming source region 150 and drain region 160 in the active region of semiconductor substrate 100, may be implanted in semiconductor substrate 100 using gate electrode 140 and spacer 125 as a mask. In one embodiment, an energy of the implantation may be from about 3 KeV to about 20 KeV and a dosage of the implantation may be from about 1×10¹⁵ ions/cm² to about 5×10¹⁵ ions/cm².

To form source/drain regions 150 and 160 of an N-channel metal-oxide-semiconductor (NMOS) transistor, arsenic (As) ions may be implanted in semiconductor substrate 100, and an ion implantation mask, such as a photoresist pattern, may be used.

Referring to FIG. 7, source region 150 and drain region 160 are formed in semiconductor substrate 100 at both sides of gate electrode 140. LDD regions 102 and 104 remain in semiconductor substrate 100 only below spacer 125.

Thus, LDD regions 102 and 104 may be shortened and overlapping of LDD regions 102 and 104 with portions below gate electrode 140 may be prevented.

Thus, the semiconductor device manufactured according to the method consistent with the present invention may have improved operational reliability.

Referring to FIG. 8, silicide layers 172, 174, and 176 are formed on source region 150, gate electrode 140, and drain region 160, respectively.

In one embodiment, silicide layers 172, 174, and 176 may be formed on source region 150, drain region 160, and gate electrode 140 using a salicide process.

Although not shown, subsequent processes, such as a metal interconnection process and a contact process of source region 150, drain region 160, and gate electrode 140, may be performed.

In one embodiment, silicide layers 172, 174, and 176 may include a metal layer having at least one of TCo, Ti, and TiN, with a high melting point and may be formed using a sputtering process.

Silicide layers 172, 174, and 176 may reduce sheet resistance and contact resistance to allow electric current to smoothly flow between metal interconnections and source region 150, drain region 160, and gate electrode 140.

Embodiments consistent with the present invention may simplify deposition, etching, cleaning processes for forming the LDD regions, so as to reduce the manufacturing time and costs.

Embodiments consistent with the present invention may prevent the diffusion of the LDD regions toward the gate electrode to minimize the leakage current and the overlap capacitance, which may improve the reliability and the operating speed of the semiconductor device. Embodiments consistent with the present invention may omit a heat-treating process for the spacer is omitted, which may prevent the degradation of a semiconductor layer due to the long-time exposure of the semiconductor device to a high-temperature environment.

Embodiments consistent with the present invention may simplify the structure of the spacer and minimize the area taken by the spacer. Accordingly, the entire size of the semiconductor device may be reduced. Finally, the area of the source region and the drain region may be increased by reducing the area taken by the spacer, thus improving the operation performance of the semiconductor device.

Any reference in this specification to “one embodiment,” “an embodiment,” “example embodiment,” etc., means that a particular feature described in connection with the embodiment is included in at least one embodiment consistent with the invention. The appearances of such phrases in various places in the specification are not necessarily all referring to the same embodiment. Further, when a particular feature is described in connection with any embodiment, it is submitted that it is within the purview of one skilled in the art to effect such feature in connection with other ones of the embodiments.

Although embodiments consistent with the present invention have been described with reference to a number of illustrative embodiments thereof, it should be understood that numerous other modifications and embodiments can be devised by those skilled in the art that will fall within the spirit and scope of the appended claims. More particularly, various variations and modifications are possible in the component parts and/or arrangements of the subject combination arrangement within the scope of the appended claims. In addition to variations and modifications in the component parts and/or arrangements, alternative uses will also be apparent to those skilled in the art.

What is claimed is:

1. A semiconductor device, comprising:
a substrate having a plurality of isolation areas formed therein, the isolation areas defining an active region;
a gate electrode formed on the active region;
spacers formed on sides of the gate electrode;
a source region formed in the substrate at a side of the spacer formed at a first side of the gate electrode;
a drain region formed in the substrate at a side of the spacer formed on a second side of the gate electrode; and
lightly doped drain regions formed in the substrate below the spacer.

2. The semiconductor device according to claim 1, further comprising a silicide layer formed on at least one of the gate electrode, the source region, and the drain region.

3. The semiconductor device according to claim 1, wherein the spacers have a rectangular shape with angled corners.

4. The semiconductor device according to claim 1, further comprising a gate dielectric layer formed between the gate electrode and the substrate.

5. A method for manufacturing a semiconductor device, the method comprising:
forming a first oxide layer on a substrate having device isolation areas formed therein;
etching a portion of the first oxide layer to expose a portion of the substrate;
forming a second oxide layer on the exposed portion of the substrate, the second oxide layer having a thickness less than that of the first oxide layer;
embedding a polysilicon layer in the etched portion of the first oxide layer;
forming spacers on sides of the polysilicon layer by etching the first oxide layer except for portions of the first oxide layer in contact with side surfaces of the polysilicon layer; and
forming lightly doped drain regions in the substrate between the device isolation areas and the spacers.

6. The method according to claim 5, wherein embedding the polysilicon layer comprises:
forming the polysilicon layer on the first oxide layer and the second oxide layer; and
planarizing the polysilicon layer to expose a surface of the first oxide layer.

7. The method according to claim 5, wherein forming the first oxide layer comprises forming the first oxide layer to have a thickness of about 1,800 Å to about 2,100 Å.

8. The method according to claim 5, further comprising forming a source region and a drain region in the lightly doped drain regions.

9. The method according to claim 8, further comprising forming a silicide layer on at least one of the polysilicon layer, the source region, and the drain region.

10. The method according to claim 5, wherein forming the lightly doped drain regions comprises forming the lightly doped regions below the spacers.

11. The method according to claim 9, wherein the silicide layer comprises at least one of TCo, Ti, and TiN.
